(19) United States
(12) Patent Application Publication
(10) Pub. No.: US 2014/0239290 A1
(43) Pub. Date: Aug. 28, 2014

(54) THIN-FILM TRANSISTOR SUBSTRATE AND METHOD OF MANUFACTURING THE SAME

(71) Applicant: SAMSUNG DISPLAY CO., LTD., Yongin-City (KR)

(72) Inventor: Hyeon Sik KIM, Yongin-City (KR)

(73) Assignee: SAMSUNG DISPLAY CO., LTD., Yongin-City (KR)

(21) Appl. No.: 14/055,933

(22) Filed: Oct. 17, 2013

(30) Foreign Application Priority Data
Feb. 25, 2013 (KR) 10-2013-0020010

(51) Int. Cl. H01L 29/786; H01L 29/66

(52) U.S. Cl. CPC H01L 29/7869; H01L 29/66742
USPC 257/43; 438/104

(57) ABSTRACT

The TFT substrate includes a gate electrode disposed on an insulating substrate; a gate insulating layer disposed on the gate electrode; a source/drain electrode disposed on the gate insulating layer; and an oxide semiconductor layer disposed between the gate insulating layer and the source/drain electrode. The oxide semiconductor layer includes a first portion that does not contact the source/drain electrode and in which a channel region is defined and a second portion in which a contact region that contacts the source/drain electrode is defined. The second portion includes a first oxide semiconductor layer and a second oxide semiconductor layer disposed on the first oxide semiconductor layer.

### CROSS-REFERENCE TO RELATED APPLICATION

Korean Patent Application No. 10-2013-0020010, filed on Feb. 25, 2013, in the Korean Intellectual Property Office, and entitled: “Thin-Film Transistor Substrate and Method of Manufacturing the Same,” is incorporated by reference herein in its entirety.

### BACKGROUND

1. Field

Embodiments relate to a thin-film transistor (TFT) substrate and a method of manufacturing the same.

2. Description of the Related Art

A thin-film transistor (TFT) typically consists of a semiconductor layer that includes a channel region, a source region, and a drain region, and a gate electrode that is on the channel region and is electrically insulated from the semiconductor layer by a gate insulating layer. The semiconductor layer of the TFT is usually formed of a semiconductor material such as amorphous silicon or polysilicon. If the active layer is formed of amorphous silicon, it is difficult to realize a driver circuit that can operate at high speed due to a low mobility. If the active layer is formed of polysilicon, a high mobility can be achieved. However, a compensation circuit is additionally required due to a non-uniform threshold voltage.

Low-temperature polysilicon (LTPS) can also be used to manufacture a TFT. However, the conventional method of manufacturing a TFT using LTPS includes expensive processes such as laser heat treatment. In addition, since it is difficult to control properties in this method, the method is not applicable for large-area substrates.

To solve the above problems, research is being conducted to use an oxide semiconductor as a semiconductor layer of a TFT.

### SUMMARY

One or more embodiments are directed to providing a thin-film transistor (TFT) substrate. The TFT substrate may include a gate electrode on an insulating substrate, a gate insulating layer on the gate electrode, a source/drain electrode on the gate insulating layer, and an oxide semiconductor layer between the gate insulating layer and the source/drain electrode. The oxide semiconductor layer may include a first portion that does not contact the source/drain electrode and in which a channel region is defined and a second portion in which a contact region that contacts the source/drain electrode is defined. The second portion may include a first oxide semiconductor layer and a second oxide semiconductor layer on the first oxide semiconductor layer.

The first portion may include the first oxide semiconductor layer. The TFT first portion may be a single layer. A thickness of the first oxide semiconductor layer in the first portion may be equal to or greater than a thickness of the first oxide semiconductor layer in the second portion.

A thickness of the second portion may be equal to or greater than a thickness of the first portion.

The oxide semiconductor layer may include one or more materials selected from InZnO, InGaO, InSnO, ZnSnO, GaSnO, GaZnO, GanSnO, GaInZnO, HfInZnO, and ZnO.

The second oxide semiconductor layer may be formed of the same material as the first oxide semiconductor layer.

The TFT substrate may include an etch stop layer disposed between the first portion and the source/drain electrode. The TFT substrate may include an oxide semiconductor pattern between the etch stop layer and the first portion. The oxide semiconductor pattern may be formed of the same material as the second oxide semiconductor layer.

One or more embodiments are directed to providing a method of manufacturing a TFT substrate. The method may include forming a gate electrode on an insulating substrate, forming a gate insulating layer on the insulating substrate and the gate electrode, forming a first oxide semiconductor film on the gate insulating layer, forming an etch stop film on the first oxide semiconductor film, forming an etch stop layer by patterning the etch stop film, forming a second oxide semiconductor film on the whole surface of the insulating substrate, forming a source/drain electrode metal film on the second oxide semiconductor film, and forming a source electrode and a drain electrode by patterning the metal film.

Forming the etch stop layer may include patterning the first oxide semiconductor film and the etch stop film simultaneously.

Before forming the etch stop film, the first oxide semiconductor film may be patterned, the etch stop film being formed on the first oxide layer and the insulating substrate.

The method may include patterning the second oxide semiconductor film at the same time as the patterning of the metal film.

The method may include patterning the second oxide semiconductor film between the forming of the second oxide semiconductor film and the forming of the metal film.

The first oxide semiconductor film or the second oxide semiconductor film may include one or more materials selected from InZnO, InGaO, InSnO, ZnSnO, GaSnO, GaZnO, GaZnSnO, GaInZnO, HfInZnO, and ZnO.

The second oxide semiconductor film may be formed of the same material as the first oxide semiconductor layer.

### BRIEF DESCRIPTION OF THE DRAWINGS

Features will become apparent to those of ordinary skill in the art by describing in detail exemplary embodiments with reference to the attached drawings in which:

FIG. 1 illustrates a cross-sectional view of a thin-film transistor (TFT) substrate according to an embodiment;

FIG. 2 illustrates a cross-sectional view of a TFT substrate according to another embodiment;

FIG. 3 illustrates a cross-sectional view of a TFT substrate according to another embodiment;

FIG. 4 illustrates a cross-sectional view of a TFT substrate according to another embodiment;

FIGS. 5 through 11 illustrate cross-sectional views of stages in a method of manufacturing a TFT substrate according to an embodiment;

FIGS. 12 and 13 illustrate cross-sectional views of stages in a method of manufacturing a TFT substrate according to another embodiment;

FIGS. 14 through 20 illustrate cross-sectional views of stages in a method of manufacturing a TFT substrate according to another embodiment; and

FIGS. 21 and 22 illustrate cross-sectional views of stages in a method of manufacturing a TFT substrate according to another embodiment.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey exemplary implementations to those skilled in the art.

In the drawing figures, the dimensions of layers and regions may be exaggerated for clarity of illustration. It will also be understood that when a layer or element is referred to as being “on” another layer or substrate, it can be directly on the other layer or substrate, or intervening layers may also be present. Further, it will be understood that when a layer is referred to as being “under” another layer, it can be directly under, and one or more intervening layers may also be present. In addition, it will also be understood that when a layer is referred to as being “between” two layers, it can be the only layer between the two layers, or one or more intervening layers may also be present. Like reference numerals refer to like elements throughout.

It will be understood that, although the terms first, second, third, etc., may be used herein to describe various elements, these elements should not be limited by these terms. These terms are only used to distinguish one element from another element. Thus, a first element discussed below could be termed a second element without departing from the teachings of the present disclosure.

Hereinafter, embodiments will be described with reference to the attached drawings.

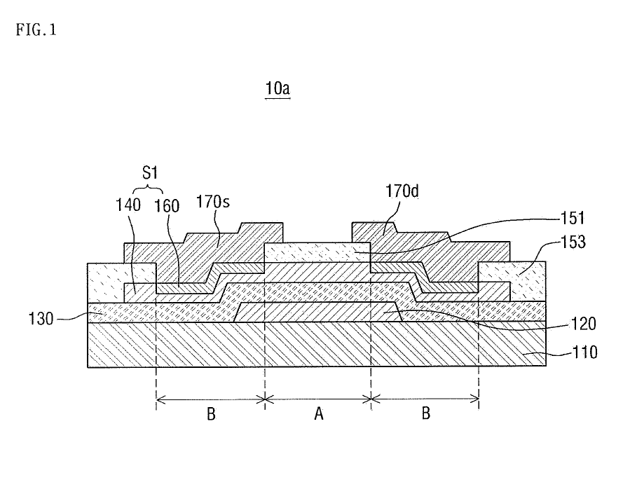

FIG. 1 illustrates a cross-sectional view of a thin-film transistor (TFT) substrate 10a according to an embodiment. Referring to FIG. 1, the TFT substrate 10a according to the current embodiment may include an insulating substrate 110, a gate electrode 120, a gate insulating layer 130, an oxide semiconductor layer S1, a source electrode 170s and a drain electrode 170d, and may further include an etch stop layer 151.

The insulating substrate 110 may be a transparent insulating substrate. For example, a transparent plastic substrate, a transparent glass substrate, or a transparent quartz substrate can be used. Further, the insulating substrate 110 may be a flexible substrate. For example, the insulating substrate 110 may be, but is not limited to, tempered glass or high hardness plastic, i.e., a combination of one or more plastic materials such as polymethyl methacrylate (PMMA), polycarbonate (PC), polyimide (PI), and polyethylene terephthalate (PET).

The gate electrode 120 may be disposed on the insulating substrate 110. The gate electrode 120 may be formed of, but not limited to, an aluminum (Al)-based metal, such as aluminum and an aluminum alloy, a silver (Ag)-based metal, such as silver and a silver alloy, a copper (Cu)-based metal, such as copper and a copper alloy, a molybdenum (Mo)-based metal, such as molybdenum and a molybdenum alloy, chromium (Cr), titanium (Ti), or tantalum (Ta). In addition, the gate electrode 120 may have a multilayer structure composed of two conductive layers (not shown) with different physical characteristics. A first of the two conductive layers may be formed of a metal with low resistivity, such as an aluminum-based metal, a silver-based metal or a copper-based metal, in order to reduce a signal delay or a voltage drop of the gate electrode 120. A second of the conductive layers may be formed of a different material, in particular, a material having superior contact characteristics with indium tin oxide (ITO) and indium zinc oxide (IZO), such as a molybdenum-based metal, chrome, titanium, or tantalum. Examples of the multilayer structure include a chrome lower layer and an aluminum upper layer, an aluminum lower layer and a molybdenum upper layer, and a titanium lower layer and a copper upper layer. However, embodiments are not limited thereto, and the gate electrode 120 may be formed of various metals and conductors.

Although not shown in FIG. 1, a buffer layer may further be disposed between the insulating substrate 110 and the gate electrode 120. The buffer layer prevents the diffusion of moisture or impurities generated from the insulating substrate 110. The buffer layer may be formed as a single layer or a multilayer using, but not limited to, an insulating layer such as silicon oxide (SiOx) or silicon nitride (SiNx).

The gate insulating layer 130 may be disposed on the insulating substrate 110 and the gate electrode 120. The gate insulating layer 130 may be SiOx, SiNx, silicon oxynitride (SiON), etc. Specifically, the gate insulating layer 130 may be formed of a single layer or a multilayer. The gate insulating layer 130 formed of a multilayer may have a stacked structure of SiNx and SiOx. For example, a portion of the gate insulating layer 130 that contacts the oxide semiconductor layer S1 may be a SiOx layer and a SiNx layer may be under the SiOx layer. The SiOx layer in contact with the oxide semiconductor layer S1 can prevent the deterioration of the oxide semiconductor layer S1. If the gate insulating layer 130 is formed of a SiON layer, the SiON layer may be made to have an oxygen concentration distribution. In this case, oxygen concentration may be made to increase as the distance to the oxide semiconductor layer S1 decreases, thereby preventing the deterioration of the oxygen semiconductor layer S1.

The oxide semiconductor layer S1 is disposed on the gate insulating layer 130. The oxide semiconductor layer S1 may include a first portion A in which a channel region of a TFT is defined and second portions B in which contact regions which respectively contact the source electrode 170s and the drain electrode 170d are defined.

The oxide semiconductor layer S1 of the TFT substrate 10a according to the current embodiment may have different stacked structures in the first and second portions A and B.

In an example, the first portion A may have a single layer structure which includes only a first oxide semiconductor layer 140, and each of the second portions B may have a multilayer structure which includes the first oxide semiconductor layer 140 and a second oxide semiconductor layer 160 on the first oxide semiconductor layer 140.

The first oxide semiconductor layer 140 of the first portion A may be thicker than the first oxide semiconductor layer 140 of the second portions B. As will be described later, the etch stop layer 151 is formed by forming an etch stop film on the oxide semiconductor layer S1 and patterning the etch stop film. Here, a portion of the etch stop film which is formed on the first portion A is not etched in order to protect the channel region. This portion of the etch stop film becomes the etch stop layer 151. On the other hand, the other portions of the etch stop film which are formed on the second portions B are etched to form the contact regions. When the etch stop film is etched to form the contact regions, the first oxide semiconductor layer 140 of the second portions B is partially etched. Consequently, the first oxide semiconductor layer 140 of the second portions B may be thinner than the first oxide semiconductor layer 140 of the first portion A.

The second oxide semiconductor layer 160 may additionally be formed on portions of the first oxide semiconductor layer 140 which were exposed to form the contact regions when the etch stop layer 151 was formed. The formation of the second oxide semiconductor layer 160 can prevent an increase in contact resistance between the source electrode 170s or the drain electrode 170d and the oxide semiconductor layer S1, the deterioration of the TFT substrate 10a, and a reduction in the performance of the TFT substrate 10a.

The second portions B of the oxide semiconductor layer S1 may be thicker than the first portion A of the oxide semiconductor layer S1. More specifically, since each of the second portions B further includes the second oxide semiconductor layer 160 formed on the partially etched first oxide semiconductor layer 140, the sum of a thickness of the first oxide semiconductor layer 140 of the second portions B and a thickness of the second oxide semiconductor layer 160 may be greater than a thickness of the first oxide semiconductor layer 140 of the first portion A. In other words, if the thickness of the second oxide semiconductor layer 160 additionally formed on the portions of the first oxide semiconductor layer 140 which were exposed to form the contact regions is greater than a thickness by which the portions of the first oxide semiconductor layer 140 were etched to form the contact regions, the second portions B may be thicker than the first portion A.

The first oxide semiconductor layer 140 and the second oxide semiconductor layer 160 may include any one material selected from InZnO, InGaO, InSnO, ZnSnO, GaSnO, GaZnO, GaZnSnO, GaInZnO, HfInZnO, and ZnO. According to another embodiment, the first oxide semiconductor layer 140 and the second oxide semiconductor layer 160 may include a compound having a chemical formula represented by AxBxOx or AxBxCxOx. A may include Zn or Cd, B may include Ga, Sn or In, and C may include Zn, Cd, Ga, In or Hf, where x is not zero, and A, B and C are different from each other. The oxide semiconductor layer S1 has a 20 to 100 times greater effective charge mobility than hydrogenated amorphous silicon, thus exhibiting excellent semiconductor properties.

The first oxide semiconductor layer 140 and the second oxide semiconductor layer 160 may be formed of the same material, for example, a material that includes GaInZnO or GIZO. However, this is merely an example. That is, the first oxide semiconductor layer 140 and the second oxide semiconductor layer 160 may also be formed of any one of the above materials. Otherwise, the first oxide semiconductor layer 140 and the second oxide semiconductor layer 160 may also be formed of different materials.

The etch stop layer 151 may be formed on the oxide semiconductor layer S1. The etch stop layer 151 formed on the first portion A of the oxide semiconductor layer S1 may function to prevent the channel region of the oxide semiconductor layer S1 from being damaged by plasma, an etching solution or an etching gas during a subsequent etching or deposition process. This is because the oxide semiconductor layer S1 damaged by the plasma, the etching solution or the etching gas can significantly deteriorate the performance of the TFT. Accordingly, the etch stop layer 151 formed on the first portion A may be wide enough to cover the channel region of the oxide semiconductor layer S1. That is, to prevent the channel region of the oxide semiconductor layer S1 from being exposed, the etch stop layer 151 may be formed in a region that overlaps the channel region and may be formed wider than the channel region in a lengthwise direction of a channel, i.e., in the plane of the page.

Etch stop patterns 153 may be formed on portions of the oxide semiconductor layer S1, excluding the first portion A and the second portions B, i.e, on ends of the oxide semiconductor layer S1. However, embodiments are not limited thereto. The etch stop patterns 153 may be formed at the same time as the etch stop layer 151. In an example, an etch stop film may be formed on the oxide semiconductor layer S1 and the insulating substrate 110 and then etched excluding its portion formed on the first portion A and portions covering the ends of the oxide semiconductor layer S1. As a result, the etch stop layer 151 and the etch stop patterns 153 may be formed simultaneously. Additionally, the etch stop patterns 153 may reduce a step difference between both ends of the source electrode 170s or between both ends of the drain electrode 170d.

The etch stop patterns 153 can have any shape. In FIG. 1, the etch stop patterns 153 cover top and side surfaces of both ends of the oxide semiconductor layer S1. However, this is merely an example, and the etch stop patterns 153 may be formed on the top surfaces of both ends of the oxide semiconductor layer S1 but may not cover the side surfaces of both ends of the oxide semiconductor layer S1.

The etch stop layer 151 and the etch stop patterns 153 may be formed of, but not limited to, SiOx, SiNx, SiON, aluminum oxide (AlxOx), silicon oxycarbide (SiOC), etc.

The source electrode 170s and the drain electrode 170d are disposed on the oxide semiconductor layer S1 and the etch stop layer 151. The source electrode 170s may extend on the oxide semiconductor layer S1 and onto the etch stop layer 170s. The drain electrode 170d may be separated from the source electrode 170s and may extend on the oxide semiconductor layer S1 and onto the etch stop layer 151 such that it is located opposite the source electrode 170s with respect to the gate electrode 120.

At least a portion of the etch stop layer 151 is exposed between the source electrode 170s and the drain electrode 170d. The oxide semiconductor layer S1 is disposed under the etch stop layer 151, the source electrode 170s and the drain electrode 170d. That is, the oxide semiconductor layer S1 may be overlapped, e.g., completely overlapped, by the etch stop layer 151, the source electrode 170s, and the drain electrode 170d.

If the etch stop patterns 153 have additionally been formed, each of the source electrode 170s and the drain electrode 170d may extend onto part of a corresponding one of the etch stop patterns 153. In this case, the oxide semiconductor layer S1 may be completely overlapped by the etch stop layer 151, the etch stop patterns 153, the source electrode 170s and the drain electrode 170d.

The source electrode 170s and the drain electrode 170d may have a single layer structure composed of Ni, Co, Ti, Ag, Cu, Mo, Al, Be, Nb, Au, Fe, Se, or Ta or may have a multilayer structure composed of these materials. In addition, an alloy of the above metal and one or more elements selected from Ti, Zr, W, Ta, Nb, Pt, Hf, O and N can be used. Examples of the multilayer structure may include a double layer such as Ti/Cu, Ta/Al, Ta/Al, Ni/Al, Co/Al or Mo(Mo alloy)/Cu and a triple layer such as Mo/Al/Mo, Ti/Al/Ti, Ta/Al/Ta, Ti/Al/TiN, Ta/Al/TaN, Ni/Al/Ni, or Co/Al/Co. However, this is merely an example, the material that forms the source electrode 170s and the drain electrode 170d is not limited to the above materials.

Although not shown in FIG. 1, an oxide semiconductor pattern may further be formed between the etch stop layer 151 and the source electrode 170s and/or between the etch stop layer 151 and the drain electrode 170d. The oxide semiconductor pattern may be formed of the same material as at least one of the materials that form the second portions B of the oxide semiconductor layer S1.

In addition, an oxide semiconductor pattern may further be formed between the etch stop pattern 153 and the source electrode 170s or between the etch stop pattern 153 and the drain electrode 170d, which will be described in greater detail later.

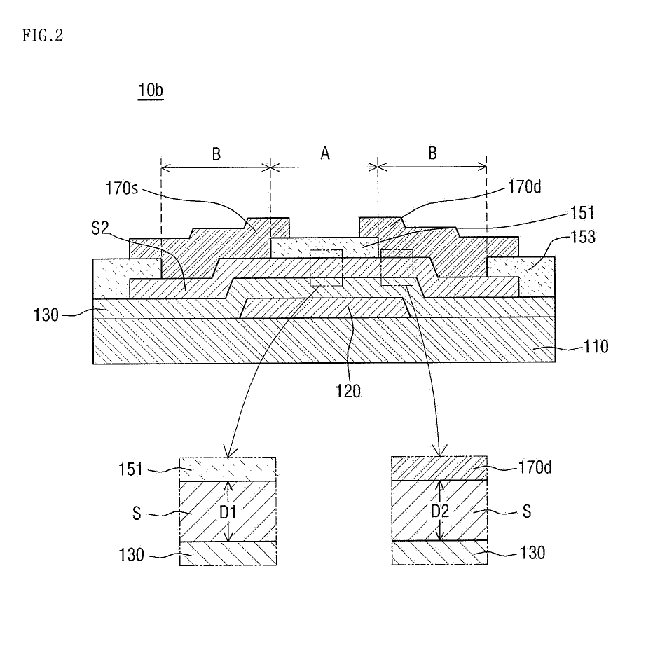

FIG. 2 illustrates a cross-sectional view of a TFT substrate 10b according to another embodiment. Referring to FIG. 2, the TFT substrate 10b according to the current embodiment may include the insulating substrate 110, the gate electrode 120, the gate insulating layer 130, an oxide semiconductor layer S2, the source electrode 170s, and the drain electrode 170d, and may further include the etch stop layer 151 and the etch stop patterns 153.

The insulating substrate 110, the gate electrode 120, the gate insulating layer 130, the etch stop layer 151, the etch stop patterns 153, the source electrode 170s, and the drain electrode 170d are identical to those of the TFT substrate 10a described above with reference to FIG. 1, and thus a detailed description thereof will be omitted.

The oxide semiconductor layer S2 may include a first portion A in which a channel region of a TFT is defined and second portions B in which contact regions that contact the source electrode 170s and the drain electrode 170d are defined.

Unlike the oxide semiconductor layer S1 of FIG. 1, the oxide semiconductor layer S2 of the TFT substrate 10b according to the current embodiment may have the same stacked structure in the first and second portions A and B.

In an example, the first portion A may have a single layer structure including a first oxide semiconductor layer, and each of the second portions B may have a single layer structure including a second oxide semiconductor layer. An example method of manufacturing the oxide semiconductor layer S2 according to the current embodiment will be described later.

A thickness D2 of the second portions B may be greater than a thickness D1 of the first portion A.

The first portion A may be formed by coating a first oxide semiconductor film on the gate insulating layer 130 and etching portions of the first oxide semiconductor film in which the contact regions are to be formed. The second portions B may be foamed by completely removing, e.g., etching, the portions of the first oxide semiconductor layer in which the contact regions are to be formed and forming the second oxide semiconductor layer in the etched portions. If the second oxide semiconductor layer is thicker than the first oxide semiconductor layer, the second portions B may be thicker than the first portion A.

The material that forms the first portion A and the material that forms the second portions B may be identical or different. More specifically, the first oxide semiconductor layer of the first portion A and the second oxide semiconductor layer of the second portions B may be formed of the same material or different materials.

Other aspects of the oxide semiconductor layer S2 (e.g., the first oxide semiconductor layer and the second oxide semiconductor layer) are identical to those of the oxide semiconductor layer S1 of FIG. 1. Thus a detailed description thereof will be omitted.

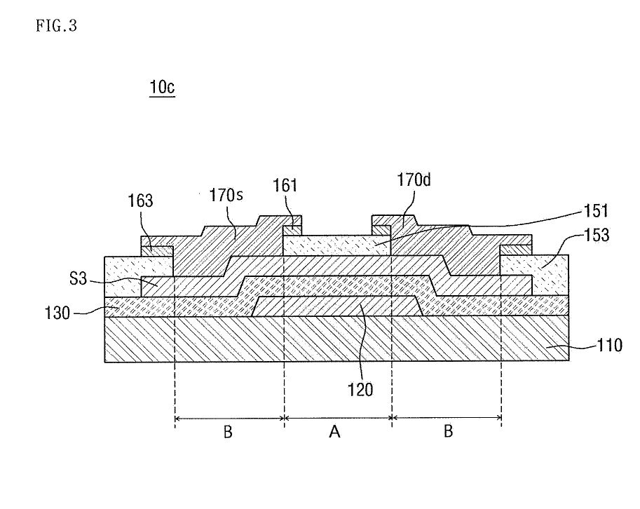

FIG. 3 illustrates a cross-sectional view of a TFT substrate 10c according to another embodiment. Referring to FIG. 3, the TFT substrate 10c according to the current embodiment may include the insulating substrate 110, the gate electrode 120, the gate insulating layer 130, an oxide semiconductor layer S3, the source electrode 170s, and the drain electrode 170d, and may further include the etch stop layer 151 and the etch stop patterns 153.

The insulating substrate 110, the gate electrode 120, the gate insulating layer 130, the etch stop layer 151, the etch stop patterns 153, the source electrode 170s, and the drain electrode 170d are identical to those of the TFT substrate 10a described above with reference to FIG. 1, and thus a detailed description thereof will be omitted.

The oxide semiconductor layer S3 may be identical to the oxide semiconductor layer S1 of FIG. 1 or the oxide semiconductor layer S2 of FIG. 2.

The TFT substrate 10c according to the current embodiment may further include an oxide semiconductor pattern 161 disposed between the etch stop layer 151 and the source electrode 170s and/or between the etch stop layer 151 and the drain electrode 170d.

The oxide semiconductor pattern 161 may be formed of the same material as at least one of the materials that form second portions B of the oxide semiconductor layer S3. In an example, if the oxide semiconductor layer S3 has the same structure as the oxide semiconductor layer S1 of FIG. 1, the oxide semiconductor pattern 161 may be formed of the same material as a second oxide semiconductor layer 160 (see FIG. 1) of the second portions B.

In addition, if the oxide semiconductor layer S3 has the same structure as the oxide semiconductor layer S2 of FIG. 2, the oxide semiconductor pattern 161 may be formed of the same material as the second portions B having a single layer structure.

Other aspects of the oxide semiconductor layer S3 are identical to those of the oxide semiconductor layers S1 and S2 of FIGS. 1 and 2. Thus, a detailed description thereof will be omitted.

If the TFT substrate 10c according to the current embodiment further includes the etch stop patterns 153, an oxide semiconductor pattern 163 may further be formed between the etch stop pattern 153 and the source electrode 170s or between the etch stop pattern 153 and the drain electrode 170d.

The oxide semiconductor pattern 161 disposed on the etch stop layer 151 may be formed of the same material as the oxide semiconductor pattern 163 disposed on each of the etch stop patterns 153.

FIG. 4 illustrates a cross-sectional view of a TFT substrate 10d according to another embodiment. Referring to FIG. 4, the TFT substrate 10d according to the current embodiment may include the insulating substrate 110, the gate electrode 120, the gate insulating layer 130, an oxide semiconductor layer S4, the source electrode 170s, and a drain electrode 170d, and may further include the etch stop layer 151 and etch stop patterns 153.

The insulating substrate 110, the gate electrode 120, the gate insulating layer 130, the etch stop layer 151, the etch stop patterns 153, and the source electrode 170s, and the drain electrode 170d are identical to those of the TFT substrate 10a described above with reference to FIG. 1. Thus, a detailed description thereof will be omitted.

The oxide semiconductor layer S4 of the TFT substrate 10d according to the current embodiment may be identical to the oxide semiconductor layer S2 of FIG. 2. In an example, the oxide semiconductor layer S4 may include a first portion A in which a channel region of a TFT is defined and second portions B in which contact regions which contact the source electrode 170s and the drain electrode 170d are defined. The oxide semiconductor layer S4 may have the same stacked structure in the first and second portions A and B. An example method of manufacturing the oxide semiconductor layer S4 according to the current embodiment will be described later.

Surface roughness R1 of a portion of the gate insulating layer 130 corresponding to the first portion A may be smaller than surface roughness R2 of portions of the gate insulating layer 130 corresponding to the second portions B. As described above with reference to FIG. 2, portions of a first oxide semiconductor film corresponding to the second portions B are completely etched to form the contact regions. In this etching process, the portions of the gate insulating layer 130 corresponding to the second portions B are also partially etched. For this reason, the surface roughness R1 of the portion of the gate insulating layer 130 corresponding to the first portion A is smaller than surface roughness R2 of the portions of the gate insulating layer 130 corresponding to the second portions B.

The surface roughness R1 or R2 of the gate insulating layer 130 may be measured in units of, but not limited to, Ra indicating the centerline average height roughness.

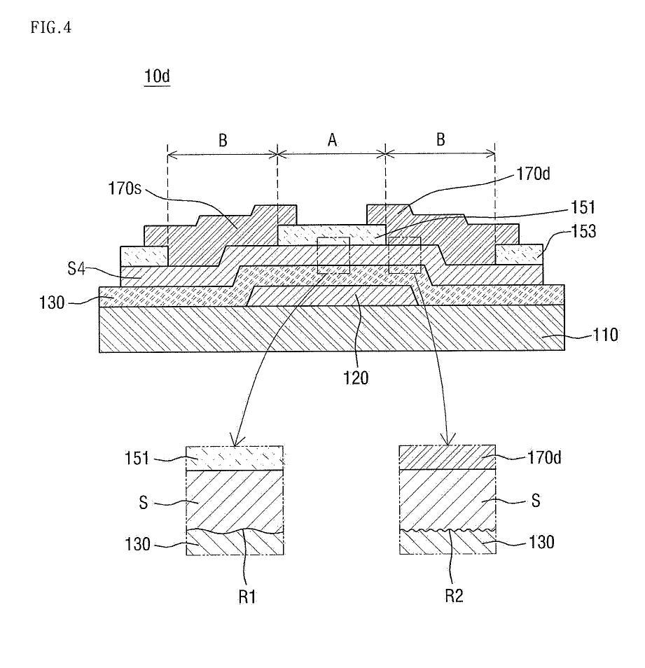

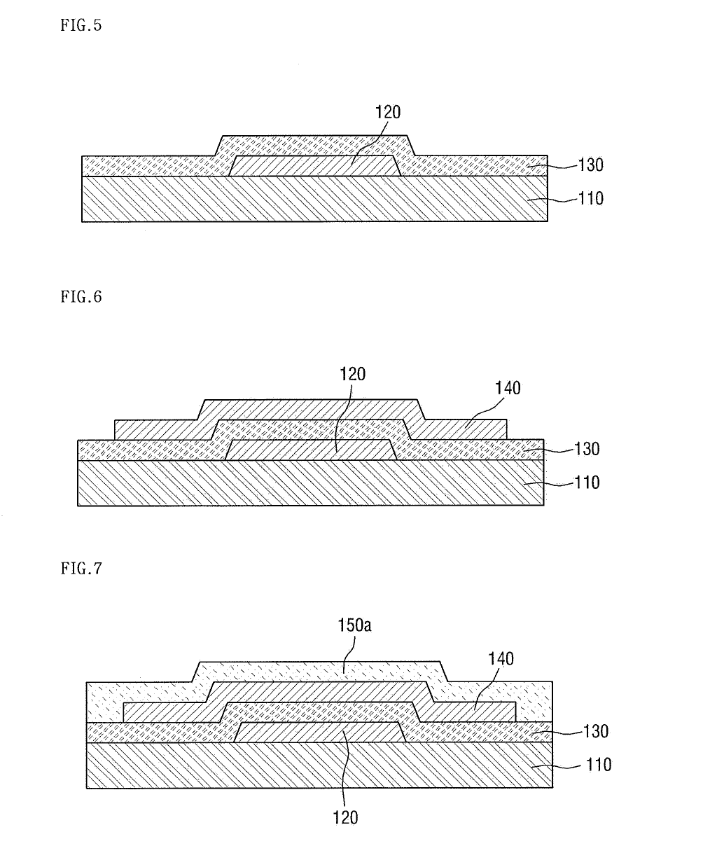

FIGS. 5 through 11 illustrate cross-sectional views of stages in a method of manufacturing a TFT substrate according to an embodiment. More specifically, FIGS. 5 through 11 illustrate cross-sectional views of stages in a method of manufacturing the TFT substrate 10a shown in FIG. 1.

Referring to FIG. 5, a metal or a metal oxide is coated on the insulating substrate 110 and then patterned to form the gate electrode 120. Examples of the metal or metal oxide that forms the gate electrode 120 have already been described above with reference to FIG. 1, thus a description there of will be omitted. After the formation of the gate electrode 120, a gate insulating layer 130 is formed on the whole surface of the insulating substrate 110 including the gate electrode 120. The gate insulating layer 130 may be formed of SiOx, SiNx, or SiON.

Referring to FIG. 6, the first oxide semiconductor layer 140 is formed on the gate insulating layer 130. The first oxide semiconductor layer 140 may be formed by depositing a first oxide semiconductor film on the gate insulating layer 130 and patterning the first oxide semiconductor film. The first oxide semiconductor film may be formed by, but not limited to, a physical vapor deposition (PVD) process, e.g., sputtering or evaporation.

Referring to FIG. 7, an etch stop film 150a is formed on the whole surface of the insulating substrate 110 including the first oxide semiconductor layer 140. The etch stop film 150a may be formed by, but not limited to, a plasma enhanced chemical vapor deposition (PECVD) process.

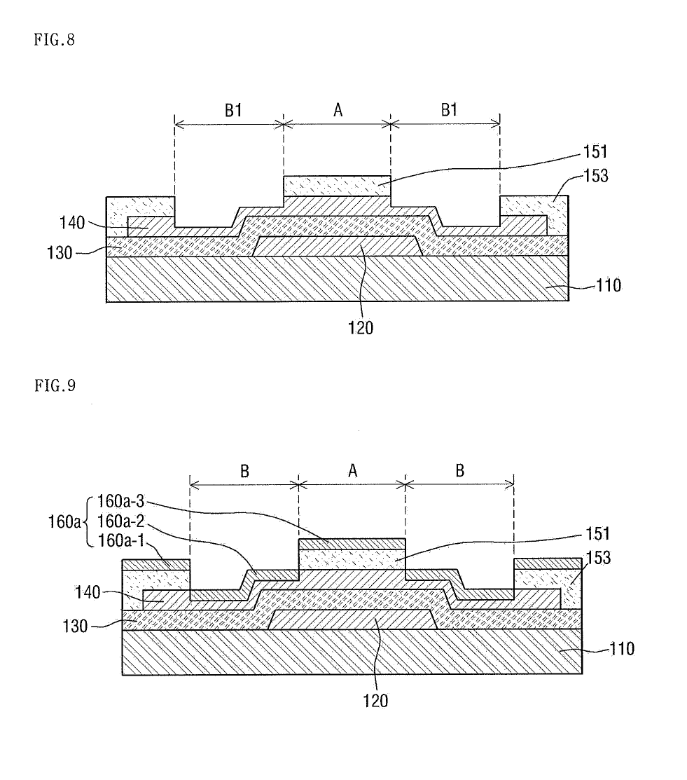

Referring to FIG. 8, the etch stop film 150a is patterned to expose portions B1 of the first oxide semiconductor layer 140, in which contact regions are to be formed, and to form a first portion A of an oxide semiconductor layer and the etch stop layer 151 on the first portion A.

The process of patterning the etch stop film 150a may be accomplished by, but not limited to, a dry-etching process, e.g., a plasma etching process.

Portions of the etch stop film 150a disposed on both ends of the first oxide semiconductor layer 140 may not be etched when the etch stop film 150a is patterned. As a result, etch stop patterns 153 may further be formed.

Referring to FIG. 9, a second oxide semiconductor film 160a is formed on the insulating substrate 110, thereby forming second portions B of the oxide semiconductor layer.

The first oxide semiconductor layer 140 can be damaged by the patterning process performed to form the etch stop layer 151 as described above with reference to FIG. 8. For example, portions of the first oxide semiconductor layer 140 corresponding to the portions B1 in which the contact regions are to be formed may be damaged by plasma or an etching gas in the above dry-etching process. Accordingly, various problems can occur, including the deterioration of electrical properties of the oxide semiconductor layer, an increase in contact resistance between a source electrode or a drain electrode and the oxide semiconductor layer, and the deterioration of the TFT. Consequently, the performance of the TFT can be significantly degraded.

However, according to the current embodiment, after the formation of the etch stop layer 151, the second oxide semiconductor film 160a is additionally formed thereby to form the second portions B of the oxide semiconductor layer. This can prevent an increase in contact resistance, the deterioration of properties of the oxide semiconductor layer, and the deterioration of the performance of the TFT.

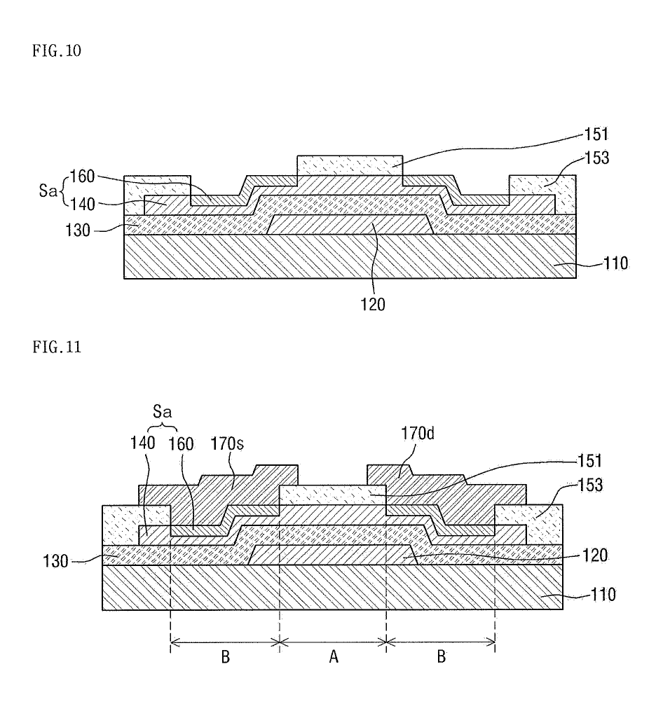

Referring to FIGS. 9 and 10, a portion 160a-3 of the second oxide semiconductor film 160a on the etch stop layer 151 is removed, e.g., by an etching process. Then, a structure including an oxide semiconductor layer Sa as shown in FIG. 10 can be obtained. If the etch stop patterns 153 have additionally been formed, portions 160a-1 disposed on the etch stop patterns 153 may also be removed.

Next, a source/drain electrode metal film is formed on the whole surface of the insulating substrate 110 and then patterned to form a source electrode 170s and a drain electrode 170d, thereby completing a TFT substrate as shown in FIG. 11. The source electrode 170s and the drain electrode 170d are separated from each other on the first portion A of the oxide semiconductor layer Sa and are electrically connected to the second portions B of the oxide semiconductor layer Sa.

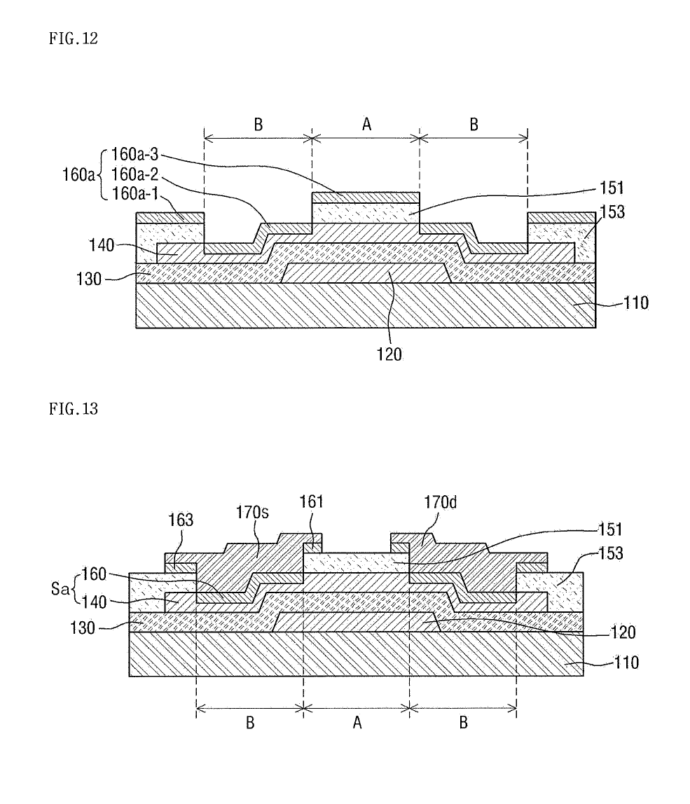

FIGS. 12 and 13 illustrate cross-sectional views of stages in a method of manufacturing a TFT substrate according to another embodiment. More specifically, FIGS. 12 and 13 illustrate cross-sectional views of stages in a method of manufacturing the TFT substrate 10c shown in FIG. 3.

A gate electrode 120, a gate insulating layer 130, a first oxide semiconductor layer 140, and an etch stop layer 151 are formed on an insulating substrate 110 using the methods described above with reference to FIGS. 5 through 8.

Then, referring to FIG. 12, a second oxide semiconductor film 160a is formed on the insulating substrate 110. Unlike in FIGS. 9 and 10, the second oxide semiconductor film 160a is not patterned, and a source/drain electrode metal film is formed on the unpatterned second oxide semiconductor film 160a.

Then, the source/drain electrode metal film and the second oxide semiconductor film 160a are patterned simultaneously, thereby completing a TFT substrate as shown in FIG. 13.

In the TFT substrate manufactured according to the current embodiment, second portions B of an oxide semiconductor layer Sa, a source electrode 170s and a drain electrode 170d may be formed simultaneously by etching the second oxide semiconductor film 160a and the source/drain electrode metal film simultaneously. Therefore, the number of patterning processes performed can be reduced compared with the manufacturing method described with reference to FIGS. 5 through 11. Accordingly, process efficiency can be improved.

In the TFT substrate manufactured according to the current embodiment, the oxide semiconductor pattern 161 is further formed between each of the source and drain electrodes 170s and 170d and the etch stop layer 151. In addition, if etch stop patterns 153 have additionally been formed, the oxide semiconductor pattern 163 may additionally be formed between each of the source and drain electrodes 170s and 170d and a corresponding one of the etch stop patterns 153.

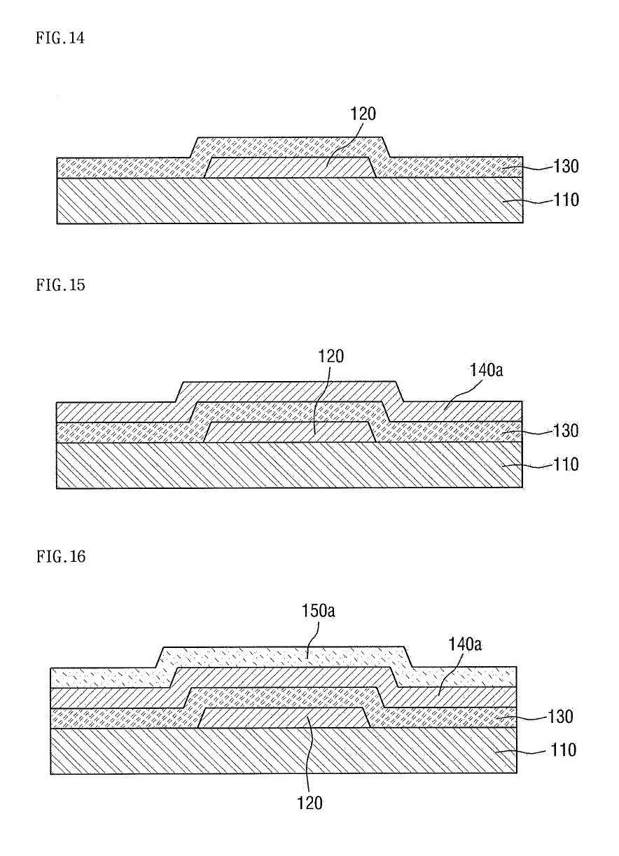

FIGS. 14 through 20 illustrate cross-sectional views of stages in a method of manufacturing a TFT substrate according to another embodiment. More specifically, FIGS. 14 through 20 illustrate cross-sectional views of stages in a method of manufacturing the TFT substrate 10b shown in FIG. 2 or the TFT substrate 10d shown in FIG. 4.

Referring to FIG. 14, the gate electrode 120 and the gate insulating layer 130 are formed sequentially on the insulating substrate 110. The method of forming the gate electrode 120 and the gate insulating layer 130 has already been described above with reference to FIG. 5, and thus a description thereof will be omitted.

Next, a first oxide semiconductor film 140a is formed on the gate insulating layer 130 as shown in FIG. 15, and an etch stop film 150a is formed on the first oxide semiconductor film 140a as shown in FIG. 16. That is, according to the current embodiment, after the formation of the first oxide semiconductor film 140a, the etch stop film 150a is formed on the first oxide semiconductor film 140a without a process of patterning the first oxide semiconductor film 140a, unlike in FIGS. 6 and 7.

Then, the first oxide semiconductor film 140a and the etch stop film 150a are patterned simultaneously to form the etch stop layer 151 and a first oxide semiconductor layer 141 which forms a first portion A of an oxide semiconductor layer, as shown in FIG. 17.

In an etching process, the etch stop film 150a and the first oxide semiconductor film 140a existing in portions B1 in which contact regions are to be formed are etched completely. Thus, upper portions of the gate insulating layer 130 corresponding to the portions B1 or upper portions of the gate insulating layer 130 corresponding to second portions (which are to be formed) of the oxide semiconductor layer are also partially etched. Accordingly, the upper portions of the gate insulating layer 130 corresponding to the contact regions or the second portions of the oxide semiconductor layer may have rougher surfaces than an upper portion of the gate insulating layer 130 corresponding to the first oxide semiconductor layer 141. That is, as described above with reference to FIG. 4, surface roughness of a portion of the gate insulating layer 130 corresponding to the first portion (which is to be formed) of the oxide semiconductor layer may be smaller than surface roughness of portions of the gate insulating layer 130 corresponding to the second portions (which are to be formed) of the oxide semiconductor layer.

In the above etching process, etch stop patterns 153 may additionally be formed. In this case, portions 143 of the first oxide semiconductor film 140a which are disposed under the etch stop patterns 153 may later become both ends of the oxide semiconductor layer.

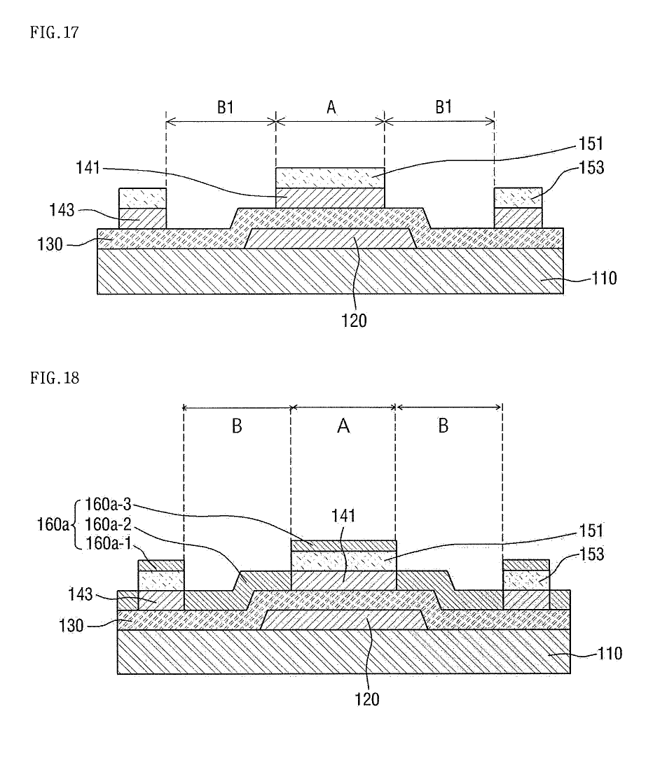

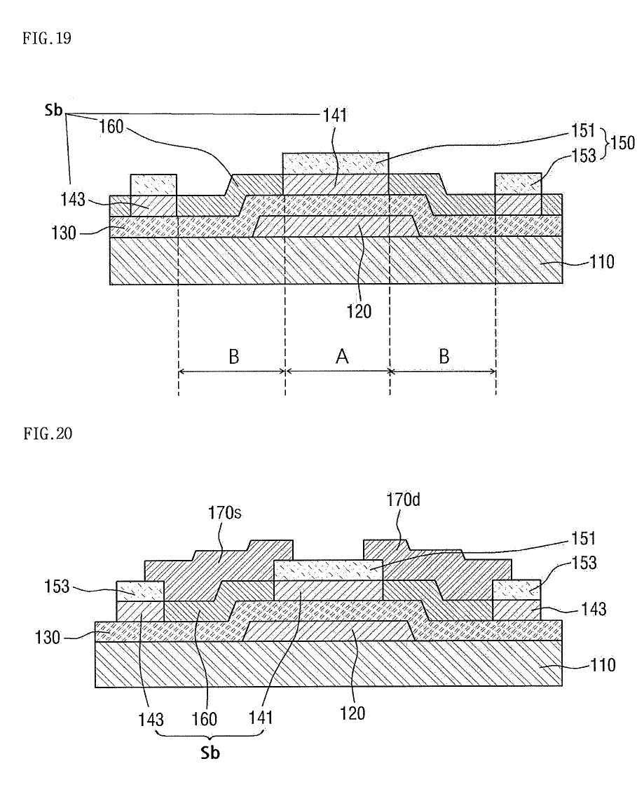

Referring to FIG. 18, a second oxide semiconductor film 160a is formed on the whole surface of the insulating substrate 110 and then patterned to remove its portions excluding portions in which the contact regions are to be formed, e.g., a portion 160a-3 disposed on the etch stop layer 151. Then, an oxide semiconductor layer Sb as shown in FIG. 19 can be obtained. Here, if the second oxide semiconductor film 160a is thicker than the first oxide semiconductor film 140a, second portions B of the oxide semiconductor layer Sb may be formed thicker than a first portion A. If the etch stop patterns 153 have additionally been formed, portions 160a-1 disposed on the etch stop patterns 153 may also be removed in the process of patterning the second oxide semiconductor film 160a.

Next, a source/drain electrode metal film is formed on the whole surface of the insulating substrate 110 and then patterned to form a source electrode 170s and a drain electrode 170d as shown in FIG. 20. The source electrode 170s and the drain electrode 170d are separated from each other on the first portion A of the oxide semiconductor layer Sb and are electrically connected to the second portions B of the oxide semiconductor layer Sb.

According to the current embodiment, the process of patterning the first oxide semiconductor film 140a can be omitted from the manufacturing method described with reference to FIGS. 5 through 11. Therefore, the manufacturing process can be simplified, and process efficiency can be improved.

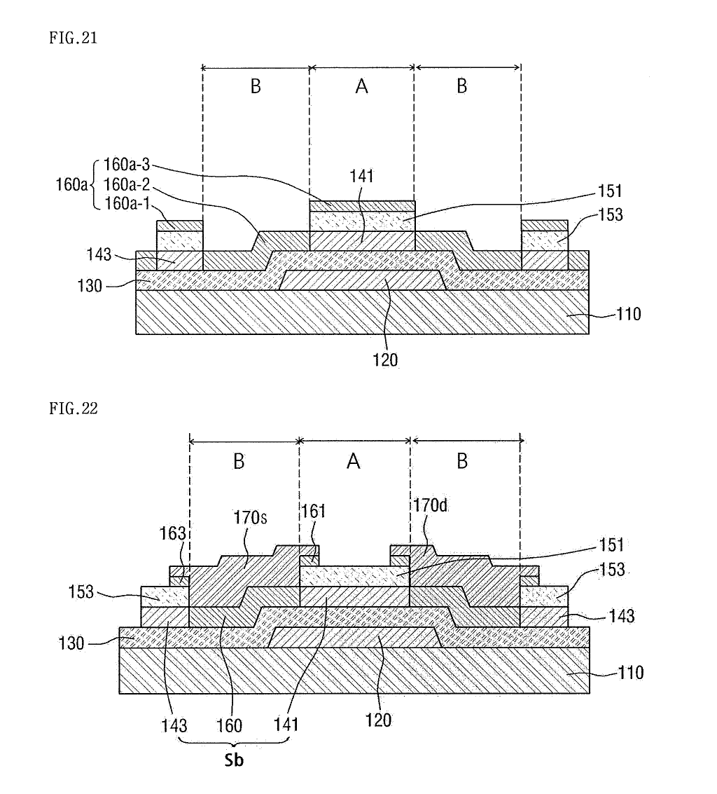

FIGS. 21 and 22 illustrate cross-sectional views of stages in a method of manufacturing a TFT substrate according to another embodiment. More specifically, FIGS. 21 and 22 are cross-sectional views of stages in a method of manufacturing the TFT substrate 10c shown in FIG. 3.

The structure shown in FIG. 21 is identical to the structure shown in FIG. 18 and can be manufactured using the method described above with reference to FIGS. 14 through 18.

A source/drain electrode metal film is formed on the unpatterned second oxide semiconductor film 160a. Then, the source/drain electrode metal film and the second oxide semiconductor film 160a are patterned simultaneously, thereby completing a TFT substrate as shown in FIG. 22.

In the TFT substrate manufactured according to the current embodiment, second portions B of an oxide semiconductor layer Sb, a source electrode 170s and a drain electrode 170d may be formed simultaneously by etching the second oxide semiconductor film 160a and the source/drain electrode metal film simultaneously. Therefore, the number of patterning processes performed can be reduced compared with the manufacturing method described above with reference to FIGS. 14 through 20.

In the TFT substrate manufactured according to the current embodiment, an oxide semiconductor pattern 161 is further formed between each of the source and drain electrodes 170s and 170d and an etch stop layer 151. If etch stop patterns 153 have additionally been formed, an oxide semiconductor pattern 163 may additionally be formed between each of the source and drain electrodes 170s and 170d and a corresponding one of the etch stop patterns 153.

When an etch stop layer is formed by coating an etch stop film and patterning the etch stop film using plasma to expose a source region and a drain region of the semiconductor layer, portions of the semiconductor layer are exposed and damaged by the plasma, thereby degrading properties of the semiconductor layer.

By way of summation and review, one or more embodiments may reduce or prevent the deterioration of electrical properties of a TFT by plasma or an etching gas can be prevented. In particular, by providing a second oxide layer before forming the source/drain electrode, deterioration of electrical properties may be prevented or redcued. Accordingly, a TFT substrate with improved reliability can be provided.

One or more embodiments may omit some of the patterning processes performed during a manufacturing process of a TFT substrate can be omitted. Therefore, process efficiency may be improved.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A thin-film transistor (TFT) substrate, comprising:
a gate electrode on an insulating substrate;
a gate insulating layer on the gate electrode;
a source/drain electrode on the gate insulating layer; and
an oxide semiconductor layer between the gate insulating layer and the source/drain electrode, the oxide semiconductor layer including:
a first portion that does not contact the source/drain electrode and in which a channel region is defined; and
a second portion in which a contact region that contacts the source/drain electrode is defined,
wherein the second portion includes a first oxide semiconductor layer and a second oxide semiconductor layer on the first oxide semiconductor layer.

2. The TFT substrate as claimed in claim 1, wherein the first portion includes the first oxide semiconductor layer.

3. The TFT substrate as claimed in claim 2, wherein the first portion is a single layer.

4. The TFT substrate as claimed in claim 2, wherein a thickness of the first oxide semiconductor layer in the first portion is equal to or greater than a thickness of the first oxide semiconductor layer in the second portion.

5. The TFT substrate as claimed in claim 1, wherein a thickness of the second portion is equal to or greater than a thickness of the first portion.

6. The TFT substrate as claimed in claim 1, wherein the oxide semiconductor layer includes one or more materials selected from InZnO, InGaO, InSnO, ZnSnO, GaSnO, GaZnO, GaZnSnO, GaInZnO, HfInZnO, and ZnO.

7. The TFT substrate as claimed in claim 1, wherein the second oxide semiconductor layer is formed of the same material as the first oxide semiconductor layer.

8. The TFT substrate as claimed in claim 1, further comprising an etch stop layer between the first portion and the source/drain electrode.

9. The TFT substrate as claimed in claim 8, further comprising an oxide semiconductor pattern between the etch stop layer and the first portion.

10. The TFT substrate as claimed in claim 9, wherein the oxide semiconductor pattern is formed of the same material as the second oxide semiconductor layer.

11. A method of manufacturing a TFT substrate, the method comprising:
forming a gate electrode on an insulating substrate;
forming a gate insulating layer on the insulating substrate and the gate electrode;
forming a first oxide semiconductor film on the gate insulating layer;
forming an etch stop film on the first oxide semiconductor film;
forming an etch stop layer by patterning the etch stop film;
forming a second oxide semiconductor film on the whole surface of the insulating substrate;
forming a source/drain electrode metal film on the second oxide semiconductor film; and
forming a source electrode and a drain electrode by patterning the metal film.

12. The method as claimed in claim 11, further comprising patterning the second oxide semiconductor film at the same time as the patterning of the metal film.

13. The method as claimed in claim 11, further comprising patterning the second oxide semiconductor film between the forming of the second oxide semiconductor film and the forming of the metal film.

14. The method as claimed in claim 11, wherein the first oxide semiconductor film or the second oxide semiconductor film includes one or more materials selected from InZnO, InGaO, InSnO, ZnSnO, GaSnO, GaZnO, GaZnSnO, GaInZnO, HfInZnO, and ZnO.

15. The method as claimed in claim 11, wherein the second oxide semiconductor film is formed of the same material as the first oxide semiconductor layer.

16. The method of claim 11, wherein forming the etch stop layer includes patterning the first oxide semiconductor film and the etch stop film simultaneously.

17. The method as claimed in claim 11, wherein, before forming the etch stop film, patterning the first oxide semiconductor film, the etch stop film being formed on the first oxide layer and the insulating substrate.
